(19) United States
(12) Patent Application Publication
(10) Pub. No.: US 2008/0225489 A1
(43) Pub. Date: Sep. 18, 2008

(54) Heat spreader with high heat flux and high thermal conductivity

(75) Inventors: Qingjun Cai, Thousand Oaks, CA (US); Chung-Lung Chen, Thousand Oaks, CA (US); Bing-Chung Chen, Newbury Park, CA (US)

Correspondence Address: KOPPEL, PATRICK & HEYBL, 555 ST. CHARLES DRIVE, SUITE 107, THOUSANDS OAKS, CA, 91360, US

(73) Assignee: TELEDYNE LICENSING, LLC

(21) Appl. No.: 11/977,251

(22) Filed: Oct. 23, 2007

Related U.S. Application Data
(60) Provisional application No. 60/854,007, filed on Oct. 23, 2006.

(51) Int. Cl. F28D 15/04; H05K 7/20

(52) U.S. Cl. 361/704; 165/104.26

(57) ABSTRACT

A heat spreader for transferring heat from a heat source to a heat sink using a phase change coolant, includes an array of cells, each cell having at least one microporous wick for supporting flows of the coolant in the liquid phase, via capillary action, within the spreader from proximate the heat sink to proximate the source and at least one macroporous wick for supporting flows of the coolant, in the liquid and vapor phase, within the spreader from proximate the source to proximate the heat sink.

### CROSS REFERENCE TO RELATED APPLICATIONS

This application claims the benefit under 35 USC 119(e) of U.S. Provisional Patent Application No. 60/854,007, filed Oct. 23, 2006.

### GOVERNMENT RIGHTS

The United States Government has rights in this invention pursuant to a contract awarded by the Defense Advanced Research Projects Agency.

### BACKGROUND OF THE INVENTION

This invention is concerned with techniques for thermal management of electronic devices and more particularly with high heat flux cooling technology for microelectronic systems.

Both the performance reliability and life expectancy of electronic equipment are inversely related to the component temperature of the equipment, with a reduction in the temperature corresponding to an exponential increase in the reliability and life expectancy of the device. Therefore, long life and reliable performance of a component may be achieved by effectively controlling the device operating temperature within the design limits for the device. One of the primary devices employed for heat dissipation in microelectronic systems is a heat sink, which absorbs and dissipates heat from a microelectronic device using thermal contact, either direct or radiant. The heat sink is typically a metal structure in contact with the electronic component's hot surface, though in most cases a thin thermal interface material mediates between the two surfaces. Microprocessors and power handling semiconductors are examples of electronics that need a heat sink to reduce their temperature through increased thermal mass and heat dissipation, primarily by conduction and convection and, to a lesser extent, by radiation.

Heat sinks function by efficiently transferring thermal energy from an object at a relatively high temperature to a second object that is at a relatively lower temperature and that has a much greater heat capacity. The goal is to effect a rapid transfer of thermal energy that quickly brings the high temperature object into thermal equilibrium with the low temperature object. Efficient functioning of a heat sink relies on the transfer of thermal energy from the first object to the heat sink at a high rate and from the heat sink to the second object. The high thermal conductivity of the heat sink material, combined with its large surface area (often provided by an array of comb or fin like protrusions), results in the rapid transfer of thermal energy to the surrounding cooler air. Fluids (such as refrigerated coolants) and thermally efficient interface materials can ensure good transfer of thermal energy to the heat sink. Similarly, a fan may improve the transfer of thermal energy from the heat sink to the air.

Heat sink performance, by mechanisms including free convection, forced convection, and liquid cooling, is a function of material, geometry, and the overall surface heat transfer coefficient. Generally, forced convection heat sink thermal performance is improved by increasing the thermal conductivity of the heat sink materials, increasing the surface area (usually by adding extended surfaces, such as fins or foamed metal) and by increasing the overall area heat transfer coefficient (usually by increasing the fluid velocity, by adding fans, coolant pumps, etc.). In addition, heat sinks may be constructed of multiple components exhibiting desirable characteristics, such as phase change materials, which can store a great deal of energy due to their heat of fusion.

When the microelectronic device is substantially smaller than the base plate of a heat sink, there is an additional thermal resistance, called the spreading resistance, which needs to be considered. Performance figures generally assume that the heat to be removed is evenly distributed over the entire base area of the heat sink and thus do not account for the additional temperature rise caused by a smaller heat source. This spreading resistance could typically be 5 to 30% of the total heat sink resistance.

Heat pipes are another useful tool that in the thermal management of microelectronics. A heat pipe can transport large quantities of heat between hot and cold regions with a very small difference in temperature. A typical heat pipe consists of a sealed hollow tube made of a thermoconductive metal such as copper or aluminum. The pipe contains a relatively small quantity of a working fluid, such as water, ethanol or mercury, with a remainder of the pipe being filled with the vapor phase of the working fluid. The advantage of heat pipes is their great efficiency in transferring heat.

The demands made on the thermal management of microelectronic systems are increasing with smaller form factors, elevated power requirements and increased bandwidth being established for next generation electronic systems. High power density, wide bandgap technology, for example, exhibits an extremely high heat flux at the device level. In addition, composite structures have low thermal mass and are not effective conductors of heat to heat sinks. The design of low cost COTS (commercial off the shelf) electronics frequently increases heat dissipation, and modern electronics is often packaged with multiple heat sources located close together. Some systems have local hot spots in particular areas, which induce thermal stress and create performance degrading issues.

These changes are resulting in an increase in the average power density, as well as higher localized power density (hot spots). As a result, the dissipation power density (waste heat flux) of electronic devices has reached several kwatts/cm² at the chip level and is projected to grow much higher in future devices. Management of such power densities is beyond the capability of traditional cooling techniques, such as a fan blowing air through a heat sink. Indeed, these power densities even exceed the performance limits of more advanced heat removal techniques, such as a liquid coolant flowing through a cold plate. A common practice to address heat spreading issues is to adopt highly conductive bulk materials or to incorporate a heat pipe as the heat spreader. These approaches, however, involve heavy components, the thermal conductivity may be too low, mechanical strength can be a limiting factor, and the heat flux may be too low. Consequently, some new electronic devices are reaching the point of being thermally limited. As a result, without higher performance thermal management systems, such devices may be hampered by being forced to operate at part of their duty cycle or at a lower power level.

Improvements are needed to increase the heat transfer coefficient, as well as to reduce the spreading resistance, primarily in the base of the heat sink. Advanced high heat flux liquid cooling technologies, based on phase change heat transfer, are needed to satisfy requirements for compact, light weight, low cost, and reliable thermal management systems.

### BRIEF SUMMARY OF THE INVENTION

A heat spreader for transferring heat from a heat source to a heat sink, using a phase change coolant, includes microporous wicks for supporting flows of the coolant in the liquid phase, via capillary action, within the spreader from proximate the heat sink to proximate the source and macroporous wicks for supporting flows of the coolant, in the liquid and vapor phase, within the spreader from proximate the source to proximate the heat sink.

The microporous wicks may be microporous nanotube wicks, while the heat spreader may be configured for positioning between a substantially planar surface of the heat source and a substantially planar surface of the heat sink, with the nanotube wicks oriented substantially perpendicular to the planar surfaces, substantially parallel to the planar surfaces, or both substantially perpendicular and substantially planar to the surfaces.

The microporous nanotube wicks may, in a particular embodiment, be microporous acid treated carbon nanotube wicks. The heat spreader may further include support structure for positioning the spreader between the heat source and the heat sink, the macroporous wicks being passageways extending through the support structure. The support structure may be silicon support structure.

In more particular embodiments, the effective size of the microporous wicks is between approximately 10 nm and approximately 1,000 nm in radius, while the macroporous wicks may be sized between approximately 1 um and approximately 500 um in radius.

Advantageously, the microporous wicks, the macroporous wicks, and the coolant of the heat spreader are configured to remove substantially all of the heat generated by the heat source, thereby maintaining the heat source at a constant temperature. The heat source will typically be a microelectronic device.

The invention also encompasses a heat spreader with a plurality of cells, each cell including at least one microporous wick for supporting flows of the coolant in the liquid phase, via capillary action, within the spreader from proximate the heat sink to proximate the source and at least one macroporous wick for supporting flows of the coolant, in the liquid and vapor phase, within the spreader from proximate the source to proximate the heat sink.

In a particular embodiment, each cell is hexagonal in cross section.

A method of transferring heat from a heat source to a heat sink, using a phase change coolant, includes, according to the invention, providing a plurality of microporous wicks for supporting flows of the coolant in the liquid phase, via capillary action, within the spreader from proximate the heat sink to proximate the source, allowing the liquid coolant to absorb heat from the heat source via vaporization, providing macroporous wicks for supporting flows of the coolant, in the liquid and vapor phase, within the spreader from proximate the source to proximate the heat sink, and allowing the vaporized coolant to condense to the liquid phase via proximity to the heat sink.

A microelectronic system, according to the invention, includes a microelectronic device, a heat sink, and a heat spreader for transferring heat from a heat source to a heat sink using a phase change coolant, the heat spreader including microporous wicks for supporting flows of the coolant in the liquid phase, via capillary action, within the spreader from proximate the heat sink to proximate the source and macroporous wicks for supporting flows of the coolant, in the liquid and vapor phase, within the spreader from proximate the source to proximate the heat sink.

### BRIEF DESCRIPTION OF THE DRAWINGS

FIG. 1 is a perspective view depicting a heat spreader constructed according to the invention.

FIG. 2 is a cross sectional, enlarged view of a portion of the cavity depicted in the heat spreader of FIG. 1.

FIG. 3 is a plan view of the portion of the cavity shown in FIG. 2.

FIG. 4 is a perspective view showing a support structure, for the heat spreader of the invention, made up of interconnecting cells.

### DETAILED DESCRIPTION OF THE INVENTION

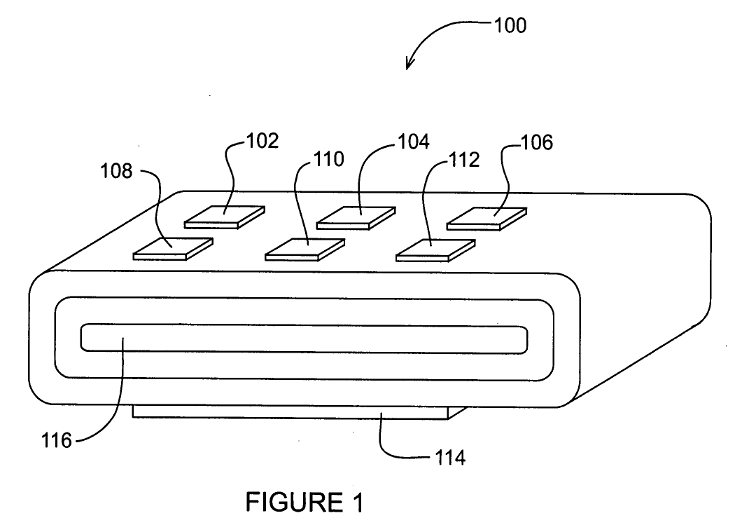

FIG. 1 is a perspective view depicting a heat spreader constructed according to this invention. The heat spreader 100 transfers heat from a heat source, such as the microelectronic circuit components 102, 104, 106, 108, 110, and 112, to a heat sink 114, using a phase change coolant, which is contained, in both vapor and liquid forms, in a cavity 116.

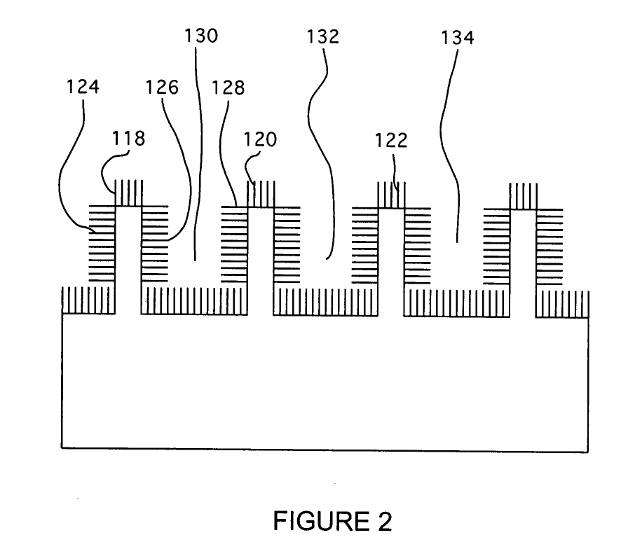

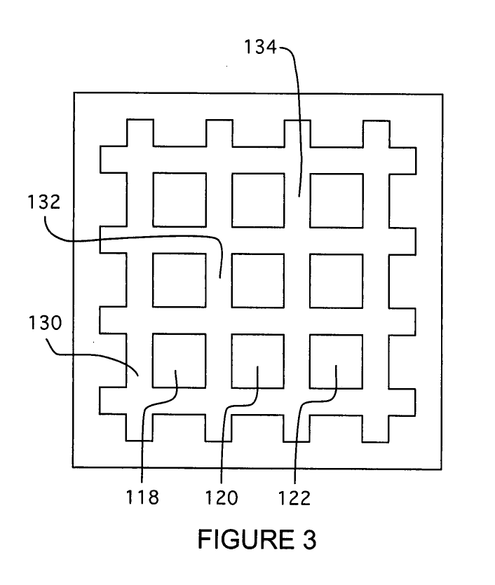

As depicted by FIG. 2, which is a cross sectional enlarged view of a portion of the heat spreader 100, and by FIG. 3, which is a plan view of the portion of the heat spreader shown in FIG. 2, surrounding the cavity 116 of the heat spreader, which is the primary location for flow of the coolant in vapor form, multiple microporous wicks, such as, for example, the wicks 118, 120, and 122, and the wicks 124, 126, and 128, support flows of the coolant in the liquid phase, via capillary action, from the heat sink to the source.

In addition, the cavity includes multiple macroporous wicks, such as, for example, the wicks 130, 132, and 134, to support flows of the coolant, in both the liquid and vapor phases, including liquid/vapor mixtures, from the source to the heat sink.

In one embodiment, the microporous wicks are microporous nanotube wicks and, in particular, may be microporous carbon nanotube wicks. Carbon nanotube wicks are typically individually grown in the spreader in areas near the heat source or attached to the macrowicks in such areas. Moreover, as depicted in FIG. 1, in a typical application, the heat spreader will be configured to be positioned between a substantially planar surface of the heat source and a substantially planar surface of the heat sink, with the heat source and heat sink surfaces being substantially parallel to each other.

The nanotube wicks may be oriented substantially perpendicular to the planar surfaces, as depicted by the wicks 118, 120, and 122, or the wicks may be oriented substantially parallel to the planar surfaces, as depicted by the wicks 124, 126, and 128. Alternatively, the wicks may include, as in the embodiment depicted in FIGS. 2 and 3, both perpendicular and parallel wicks.

In more particular embodiments of the heat spreader, the effective pore size of the microporous wicks is very small, with a high flow resistance, and will range between approximately 10 nm and 1,000 nm in radius. This provides a high capillary pressure for liquid pumping. Microporous nanotube wicks, when grown on an internal surface of the heat spreader, will typically range in height from approximately 100 to 2,000 microns. The microwicks will preferably be connected to the macrowicks to provide a continuous supply route for liquid coolant. When the microwicks are attached to the macrowicks, the microwicks will typically range in height from 1 to 1,000 microns. The pore size of the macroporous wicks will range between approximately 1 and 500 microns.

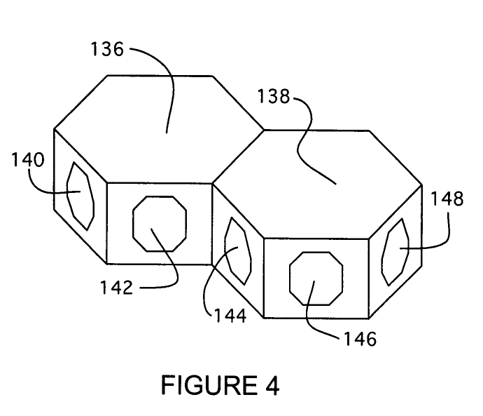

The heat spreader may include, in addition, support structure for positioning the spreader between substantially planar surfaces of the heat source and the heat sink. This embodiment is depicted in FIG. 4, which is a perspective view showing a support structure made up of interconnecting cells, with cells 136 and 138 shown. In one embodiment, this support structure is fabricated out of silicon, or can be made from metal materials. Each cell includes multiple macroporous wicks, such as the wicks 140 and 142 in cell 136, as well as the wicks 144, 146, and 148 in cell 138.

Each cell made of silicon or metal materials may include, in one approach to fabrication, an upper piece and a lower piece, symmetrical in geometry. Both the upper and lower pieces could be gold bonded, then reinforced by epoxy poured into a pre-etched cavity. The heat spreader structure can be, for example, a non-metallic material, such as silicon, SiC or SiNa, or a metallic material, such as copper, aluminum or silver. For a non-metallic structure, the fabrication process would typically use a dry or wet etch MEMS (microelectromechanical system) process. For a metallic structure, fabrication process would typically employ the sintering of metal particles.

The macroporous wicks establish passageways that extend through the cellular support structure in a direction substantially parallel to the planar surfaces. Although the scale of FIG. 4 is too small to properly represent them, the interior surfaces of the cells 136 and 138 also contain microporous wicks, similar to the microporous wicks depicted in FIGS. 2 and 3.

As shown in FIG. 4, in one embodiment the cells making up the support structure are hexagonal in cross section, although as those skilled in the pertinent art will appreciate, other geometric shapes for the cells, such as, for example, a triangular cross section, may be possible and desirable for particular applications of the heat spreader. In this two phase cell design, each cell is coated with bi-wick structures made of both macroparticles and nanoparticles.

Only a very small amount of liquid coolant is needed, to cover the wick structure. The cavity is primarily occupied by saturated coolant vapor. The macroparticles incorporate relatively large pores, to reduce pressure losses in the liquid flow attributable to viscosity, while the microwicks generate large capillary forces to circulate the liquid coolant within the spreader, without the need for an external pump.

The phase change involves the absorption and release of a large amount of latent heat at the evaporation and condensation regions of the spreader. With the proper sizing of components, this allows the heat spreader of this invention to operate with no net rise in temperature. This mechanism, which is the cornerstone of modern heat pipe technology, is very efficient for heat transfer. The incorporation of nanotechnology in this invention allows heat pipe technology to advance to a new level of performance and to be integrated into a multifunctional structural material, making possible a significant increase in the thermal mass of composite structures.

The preferred embodiments of this invention have been illustrated and described above. Modifications and additional embodiments, however, will undoubtedly be apparent to those skilled in the art. Furthermore, equivalent elements may be substituted for those illustrated and described herein, parts or connections might be reversed or otherwise interchanged, and certain features of the invention may be utilized independently of other features. Consequently, the exemplary embodiments should be considered illustrative, rather than inclusive, while the appended claims are more indicative of the full scope of the invention.

1. A heat spreader for transferring heat from a heat source to a heat sink using a phase change coolant, comprising:
a plurality of microporous wicks for supporting flows of the coolant in the liquid phase, via capillary action, within the spreader from proximate the heat sink to proximate the source; and
a plurality of macroporous wicks for supporting flows of the coolant, in the liquid and vapor phase, within the spreader from proximate the source to proximate the heat sink.

2. The heat spreader of claim 1, wherein the microporous wicks further comprise microporous nanotube wicks.

3. The heat spreader of claim 2, wherein:
the heat spreader is configured to be positioned between a substantially planar surface of the heat source and a substantially planar surface of the heat sink, the surface of the heat sink being substantially parallel to the surface of the heat source; and
the nanotube wicks are oriented substantially perpendicular to the planar surfaces.

4. The heat spreader of claim 2, wherein:
the heat spreader is configured to be positioned between a substantially planar surface of the heat source and a substantially planar surface of the heat sink, the surface of the heat sink being substantially parallel to the surface of the heat source; and
the nanotube wicks are oriented substantially parallel to the planar surfaces.

5. The heat spreader of claim 4, wherein the plurality of microporous nanotube wicks is a first plurality of microporous nanotube wicks, and further comprising a second plurality of microporous nanotube wicks for supporting flows of the coolant in the liquid phase, via capillary action, within the spreader from proximate the heat sink to proximate the source, the second plurality of, the second plurality of nanotube wicks being oriented substantially perpendicular to the planar surfaces.

6. The heat spreader of claim 2, wherein the microporous nanotube wicks further comprise microporous carbon nanotube wicks.

7. The heat spreader of claim 1, wherein:
the heat spreader further comprises support structure for positioning the spreader between a substantially planar surface of the heat source and a substantially planar surface of the heat sink, the surface of the heat sink being substantially parallel to the surface of the heat source; and.
the macroporous wicks further comprise passageways extending through the support structure in a direction substantially parallel to the planar surfaces.

8. The heat spreader of claim 7, wherein the support structure further comprises silicon support structure.

9. The heat spreader of claim 1, wherein:
the effective pore size of the microporous wicks is between approximately 10 nm and approximately 1,000 nm in radius.

10. The heat spreader of claim 1, wherein:
the effective pore size of the macroporous wicks is between approximately 1 um and approximately 500 um in radius.

11. The heat spreader of claim 1, wherein the microporous wicks, the macroporous wicks, and the coolant of the heat spreader are configured to remove substantially all of the heat generated by the heat source, thereby maintaining the heat source at a constant temperature.

12. The heat spreader of claim 1, wherein the heat source comprises a microelectronic device.

13. A heat spreader, to be positioned between a substantially planar surface of a heat source and a substantially planar surface of a heat sink, the surface of the heat sink being substantially parallel to the surface of the heat source, for transferring heat from the heat source to the heat sink using a phase change coolant, comprising:
a silicon support structure for positioning the spreader between the surface of the heat source and the surface of the heat sink;
a first plurality of microporous carbon nanotube wicks, affixed to the support structure substantially perpendicular to the heat source and heat sink surfaces, for supporting flows of the coolant in the liquid phase, via capillary action, within the spreader from proximate the heat sink to proximate the source;
a second plurality of microporous carbon nanotube wicks, affixed to the support structure substantially parallel to the heat source and heat sink surfaces, for supporting flows of the coolant in the liquid phase, via capillary action, within the spreader from proximate the heat sink to proximate the source; and
a plurality of macroporous wicks, extending through the support structure and substantially parallel to the heat source and heat sink surfaces, for supporting flows of the coolant, in the liquid and vapor phase, within the spreader from proximate the source to proximate the heat sink.

14. A heat spreader for transferring heat from a heat source to a heat sink using a phase change coolant, comprising:
a plurality of cells, each cell including:
at least one microporous wick for supporting flows of the coolant in the liquid phase, via capillary action, within the spreader from proximate the heat sink to proximate the source; and
at least one macroporous wick for supporting flows of the coolant, in the liquid and vapor phase, within the spreader from proximate the source to proximate the heat sink.

15. The heat spreader of claim 14, wherein:
the heat spreader is configured to be positioned between a substantially planar surface of the heat source and a substantially planar surface of the heat sink, the surface of the heat sink being substantially parallel to the surface of the heat source; and
each cell is hexagonal in cross section.

16. A heat spreader, to be positioned between a substantially planar surface of a heat source and a substantially planar surface of a heat sink, the surface of the heat sink being substantially parallel to the surface of the heat source, for transferring heat from the heat source to the heat sink using a phase change coolant, comprising:
a silicon support structure for positioning the spreader between the surface of the heat source and the surface of the heat sink; and
an array of hexagonal cells within the support structure, each cell including:
a first plurality of microporous carbon nanotube wicks, affixed to the support structure substantially perpendicular to the heat source and heat sink surfaces, for supporting flows of the coolant in the liquid phase, via capillary action, within the spreader from proximate the heat sink to proximate the source;
a second plurality of microporous carbon nanotube wicks, affixed to the support structure substantially parallel to the heat source and heat sink surfaces, for supporting flows of the coolant in the liquid phase, via capillary action, within the spreader from proximate the heat sink to proximate the source; and
a plurality of macroporous wicks, extending through the support structure and substantially parallel to the heat source and heat sink surfaces, for supporting flows of the coolant, in the liquid and vapor phase, within the spreader from proximate the source to proximate the heat sink.

17. A method of transferring heat from a heat source to a heat sink using a phase change coolant, comprising:
providing a plurality of microporous wicks for supporting flows of the coolant in the liquid phase, via capillary action, within the spreader from proximate the heat sink to proximate the source;
allowing the liquid coolant to absorb heat from the heat source via vaporization;
providing a plurality of macroporous wicks for supporting flows of the coolant, in the liquid and vapor phase, within the spreader from proximate the source to proximate the heat sink; and
allowing the vaporized coolant to condense to the liquid phase via proximity to the heat sink.

18. The method of claim 17, wherein a substantially planar surface of the heat source is substantially parallel to a substantially planar surface of the heat sink, and wherein the step of providing a plurality of microporous wicks further comprises:
providing a plurality of microporous wicks for supporting flows of the coolant in the liquid phase, via capillary action, within the spreader from proximate the heat sink to proximate the source and in a direction substantially perpendicular to the planar surfaces.

19. The method of claim 17, wherein a substantially planar surface of the heat source is substantially parallel to a substantially planar surface of the heat sink, and wherein the step of providing a plurality of microporous wicks further comprises:
providing a plurality of microporous wicks for supporting flows of the coolant in the liquid phase, via capillary action, within the spreader from proximate the heat sink to proximate the source and in a direction substantially parallel to the planar surfaces.

20. The method of claim 19, wherein the step of providing a plurality of microporous wicks comprises providing a first plurality of microporous wicks, and further comprising:
providing a second plurality of microporous wicks for supporting flows of the coolant in the liquid phase, via capillary action, within the spreader from proximate the heat sink to proximate the source and in a direction substantially perpendicular to the planar surfaces.

21. The method of claim 17, wherein a substantially planar surface of the heat source is substantially parallel to a substantially planar surface of the heat sink, and wherein the step of providing a plurality of macroporous wicks further comprises:
providing a plurality of macroporous wicks for supporting flows of the coolant in the liquid and vapor phase from the source to the heat sink and in a direction substantially parallel to the planar surfaces.

22. A method of transferring heat from a heat source to a heat sink using a phase change coolant, comprising:
providing a plurality of cells;
providing each cell with:
at least one microporous wick for supporting flows of the coolant in the liquid phase, via capillary action, within the spreader from proximate the heat sink to proximate the source; and
at least one macroporous wick for supporting flows of the coolant, in the liquid and vapor phase, within the spreader from proximate the source to proximate the heat sink
allowing the liquid coolant to absorb heat from the heat source via vaporization; and
allowing the vaporized coolant to condense to the liquid phase via proximity to the heat sink.

23. A microelectronic system, comprising:
a microelectronic device;
a heat sink; and
a heat spreader for transferring heat from a heat source to a heat sink using a phase change coolant, including
a plurality of microporous wicks for supporting flows of the coolant in the liquid phase, via capillary action, within the spreader from proximate the heat sink to proximate the source; and
a plurality of macroporous wicks for supporting flows of the coolant, in the liquid and vapor phase, within the spreader from proximate the source to proximate the heat sink.

24. A microelectronic system, comprising:
a microelectronic device;
a heat sink; and
a heat spreader for transferring heat from a heat source to a heat sink using a phase change coolant, including
a plurality of cells, each cell including:
at least one microporous wick for supporting flows of the coolant in the liquid phase, via capillary action, within the spreader from proximate the heat sink to proximate the source; and
at least one macroporous wick for supporting flows of the coolant, in the liquid and vapor phase, within the spreader from proximate the source to proximate the heat sink.
